(19) United States
(12) Patent Application Publication
(10) Pub. No.: US 2006/0121742 A1
(43) Pub. Date: Jun. 8, 2006

(54) Method for making a semiconductor device having a high-k gate dielectric

(75) Inventors: Matthew V. Metz, Hillsboro, OR (US); Suman Datta, Beaverton, OR (US); Jack Kavalieros, Portland, OR (US); Mark L. Doczy, Beaverton, OR (US); Justin K. Brask, Portland, OR (US); Robert S. Chau, Beaverton, OR (US)

Correspondence Address: INTEL CORPORATION, P.O. BOX 5326, SANTA CLARA, CA, 95056-5326, US

(73) Assignee: Intel Corporation

(21) Appl. No.: 11/006,438

(22) Filed: Dec. 7, 2004

(51) Int. Cl. H01L 21/336

(52) U.S. Cl. 438/778

(57) ABSTRACT

A method for making a semiconductor device is described. That method comprises applying an atomic layer chemical vapor deposition process to form a high-k gate dielectric layer directly on a hydrophobic surface of a substrate. The atomic layer chemical vapor deposition process initiates growth of the high-k gate dielectric layer in less than about twenty growth cycles.

### FIELD OF THE INVENTION

The present invention relates to methods for making semiconductor devices, in particular, those that include high-k gate dielectric layers.

### BACKGROUND OF THE INVENTION

MOS field-effect transistors with very thin silicon dioxide based gate dielectrics may experience unacceptable gate leakage currents. Forming the gate dielectric from certain high-k dielectric materials, instead of silicon dioxide, can reduce gate leakage. Before using conventional precursors to form a high-k gate dielectric on a silicon substrate, it may be necessary to treat the substrate's surface with an aqueous solution that contains hydrogen peroxide. Exposing that surface to such a solution may generate a buffer layer (e.g., a thin layer of silicon dioxide) on the silicon substrate.

The presence of such a buffer layer between the substrate and the high-k gate dielectric may, however, contribute to the overall electrical thickness of the gate dielectric stack. As devices continue to shrink, it may be desirable to decrease the electrical thickness by eliminating that buffer layer.

Accordingly, there is a need for an improved process for making a semiconductor device that includes a high-k gate dielectric. There is a need for a process for forming such a device that does not form the high-k gate dielectric on a buffer layer, which is formed on an underlying substrate. The method of the present invention provides such a process.

### BRIEF DESCRIPTION OF THE DRAWINGS

FIGS. 1a-1c represent cross-sections of structures that may be formed when carrying out an embodiment of the method of the present invention.

FIGS. 2a-2b represent cross-sections of structures that may be formed when carrying out a second embodiment of the method of the present invention.

Features shown in these figures are not intended to be drawn to scale.

### DETAILED DESCRIPTION OF THE PRESENT INVENTION

A method for making a semiconductor device is described. That method comprises applying an atomic layer chemical vapor deposition process to form a high-k gate dielectric layer directly on a hydrophobic surface of a substrate. The atomic layer chemical vapor deposition process initiates growth of the high-k gate dielectric layer in less than about twenty growth cycles. In the following description, a number of details are set forth to provide a thorough understanding of the present invention. It will be apparent to those skilled in the art, however, that the invention may be practiced in many ways other than those expressly described here. The invention is thus not limited by the specific details disclosed below.

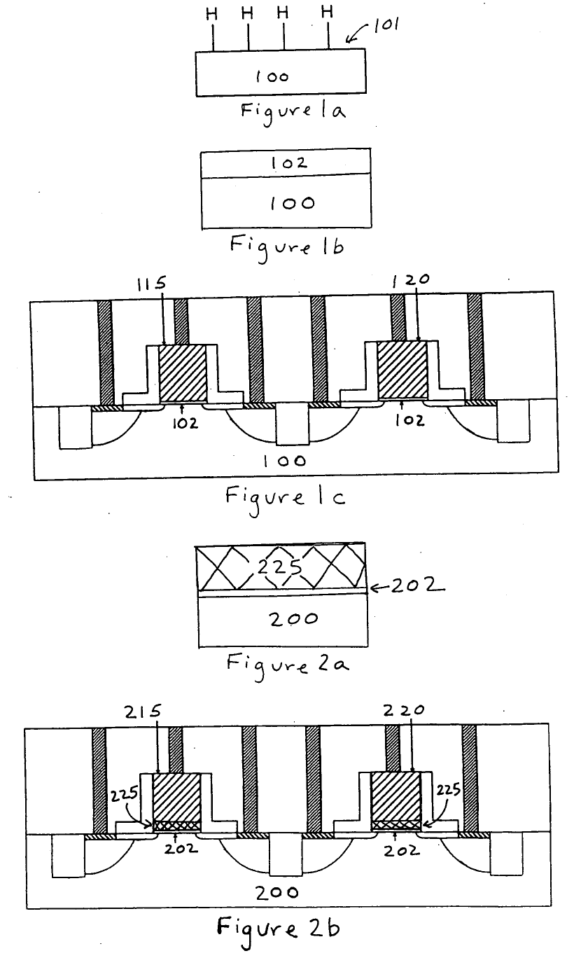

FIGS. 1a-1c represent cross-sections of structures that may be formed when carrying out an embodiment of the method of the present invention. FIG. 1a represents substrate 100, which includes hydrophobic surface 101. Substrate 100 may comprise any material that may serve as a foundation upon which a semiconductor device may be built. Substrate 100 may, for example, comprise silicon and/or germanium.

When substrate 100 comprises a silicon wafer, hydrophobic surface 101 may be formed on silicon containing substrate 100 by exposing that substrate to a reducing agent, e.g., a reducing agent that comprises hydrogen. In a preferred embodiment, silicon containing substrate 100 is exposed to a 1% hydrofluoric acid solution for about 60 seconds to generate hydrophobic surface 101. It is believed that exposing silicon containing substrate 100 to such a solution will remove any native oxide that may be present on substrate 100, and will subsequently cause hydrogen atoms to bond to its surface (as FIG. 1a indicates), yielding a hydrophobic surface.

After forming hydrophobic surface 101 on silicon containing substrate 100, high-k gate dielectric layer 102 is formed directly on hydrophobic surface 101, as FIG. 1 b illustrates. High-k gate dielectric layer 102 may comprise, for example, hafnium oxide, lanthanum oxide, zirconium oxide, titanium oxide, tantalum oxide, yttrium oxide, and aluminum oxide. Particularly preferred are hafnium oxide, lanthanum oxide, zirconium oxide, and aluminum oxide. Although a few examples of materials that may be used to form dielectric layer 102 are described here, that layer may be made from other materials that serve to reduce gate leakage.

In the method of the present invention, high-k gate dielectric layer 102 is formed on substrate 100 via an atomic layer chemical vapor deposition (“ALCVD”) process. In a conventional ALCVD process, a growth cycle is repeated until a high-k gate dielectric layer of a desired thickness is created. Typically, such a growth cycle comprises the following sequence. Steam is introduced into a CVD reactor for a selected pulse time, followed by a purging gas. A conventional precursor (e.g., a metal chloride) is then pulsed into the reactor, followed by a second purge pulse. While operating the reactor at a selected pressure and maintaining the substrate at a selected temperature, steam, the purging gas, and the precursor are, in turn, fed at selected flow rates into the reactor. By repeating this growth cycle—steam, purging gas, precursor, and purging gas—multiple times, one may create a high-k gate dielectric layer of a desired thickness on the substrate.

When using an ALCVD process to form a high-k gate dielectric layer from a conventional precursor, it is standard practice to form that layer on a hydrophilic surface for the following reason. If such a process is used to form a metal oxide dielectric layer on a substrate with a hydrophobic surface, the induction time may be unacceptably long and the resulting film may have degraded gate dielectric properties.

If a conventional precursor is used in an ALCVD process to form a high-k gate dielectric layer on a hydrophobic surface, it may require 30 to 40 growth cycles to initiate growth of that layer. If 60 to 80 growth cycles are sufficient to generate a layer with the desired thickness, then the induction period may appropriate about 50% of the time required to grow the film. Even if possible to generate such a layer on a hydrophobic surface using a conventional precursor in an ALCVD process, the resulting film may be nonuniform and unreliable. In addition, the film may contain an unacceptable level of impurities, and may have undesirable leakage and capacitance properties.

Unlike a conventional ALCVD process, the method of the present invention initiates growth of a high quality high-k gate dielectric layer on a hydrophobic surface in less than about twenty growth cycles. In a preferred embodiment, each growth cycle comprises introducing steam, then a purging gas, into a CVD reactor, and introducing a metal alkoxide precursor, then the purging gas, into the reactor. Whether the initial growth cycle begins with steam or the precursor may depend upon the equipment and operating parameters used, and upon the desired properties for the resulting film.

In a particularly preferred embodiment, the metal alkoxide precursor has the molecular formula M(OR)_{y}, in which M is a metal such as hafnium, lanthanum, zirconium, titanium, tantalum, yttrium or aluminum, R is an alkyl group (e.g., an ethyl, propyl, isopropyl, t-butyl, or neopentyl group), and y is between 3 and 5. Hf(O^{t}Bu)₄ is an example of a metal alkoxide that may be used. The purging gas may comprise nitrogen or another inert species, e.g., helium or argon.

When using such a metal alkoxide precursor in an ALCVD process to form high-k gate dielectric layer 102, the metal alkoxide precursor and steam may be alternately fed at selected flow rates into a CVD reactor, which is operated at a selected pressure while maintaining substrate 100 at a selected temperature. A carrier gas that comprises nitrogen or another inert gas may be injected into the reactor at the same time. The CVD reactor should be operated long enough to form a layer with the desired thickness. In most applications, high-k gate dielectric layer 102 should be less than about 40 angstroms thick, and more preferably between about 5 angstroms and about 20 angstroms thick.

When processing a single wafer, each pulse may take less than a second or up to about 30 seconds—whether steam or the metal alkoxide precursor is fed into the reactor. When simultaneously processing multiple wafers, the pulse times may instead be on the order of minutes. In most applications, between about 10 growth cycles and about 40 growth cycles should be sufficient to produce a high-k gate dielectric layer of the desired thickness. Even when applying relatively short pulse times, it may, for example, require only about 20 growth cycles to generate a hafnium oxide film that is about 20 angstroms thick using a Hf(O^{t}Bu)₄ precursor.

The order in which various gases are introduced into the reactor, and the number of pulses for each gas at each stage, may be varied to suit a particular application. For example, although in some embodiments each stage of a growth cycle will consist of a single pulse of each gas, in other embodiments a stage may consist of multiple pulses of a summoned gas. The pressure at which the reactor is operated, the gases' flow rates, and the temperature at which the substrate is maintained may be varied depending upon the application and the metal alkoxide precursor that is used.

After forming high-k gate dielectric layer 102 on substrate 100, metal gate electrodes 1 15 and 120 may be formed on the high-k gate dielectric layer 102 to generate the structure of FIG. 1c. Various techniques for generating that structure will be apparent to those skilled in the art. Metal gate electrodes 115 and 120 may comprise any conductive material from which metal gate electrodes may be derived. Metal gate electrode 115 may comprise an NMOS metal gate electrode, while metal gate electrode 120 comprises a PMOS metal gate electrode. Alternatively, metal gate electrode 115 may comprise a PMOS metal gate electrode, while metal gate electrode 120 comprises an NMOS metal gate electrode.

Materials that may be used to form n-type metal gate electrodes include: hafnium, zirconium, titanium, tantalum, aluminum, their alloys (e.g., metal carbides that include these elements, i.e., hafnium carbide, zirconium carbide, titanium carbide, tantalum carbide, and aluminum carbide), and aluminides (e.g., an aluminide that comprises hafnium, zirconium, titanium, tantalum, or tungsten). Materials for forming p-type metal gate electrodes include: ruthenium, palladium, platinum, cobalt, nickel, and conductive metal oxides, e.g., ruthenium oxide.

Metal NMOS gate electrodes preferably have a workfunction that is between about 3.9 eV and about 4.2 eV. Metal PMOS gate electrodes preferably have a workfunction that is between about 4.9 eV and about 5.2 eV. FIG. 1c represents structures in which the metal gate electrodes consist essentially of a homogeneous metal layer. In alternative embodiments, the n-type or p-type metal layers may generate only the lower part of the metal gate electrodes, with the remainder of the metal gate electrodes comprising another metal or metals, e.g., a metal that may be easily polished like tungsten, aluminum, titanium, or titanium nitride. Although a few examples of materials for forming metal gate electrodes 115 and 120 are identified here, those metal gate electrodes may be made from many other materials, as will be apparent to those skilled in the art. Moreover, although gate electrodes 115 and 120 preferably are metal gate electrodes, they may alternatively comprise polysilicon or a silicide.

FIGS. 2a-2b represent cross-sections of structures that may be formed when carrying out a second embodiment of the method of the present invention. In this second embodiment, a seed layer is formed on a hydrophobic surface of a substrate. A high-k gate dielectric layer is then formed on the seed layer using an ALCVD process that employs a conventional metal halide precursor. Such a process may be preferred over the embodiment described above if a high-k gate dielectric layer formed from a metal halide precursor provides film properties for a particular application that are preferred over those of a high-k gate dielectric layer formed from a metal alkoxide precursor.

In this embodiment, silicon containing substrate 200 may be exposed to hydrofluoric acid to generate a hydrophobic surface on substrate 200. Seed layer 202 may then be formed on the hydrophobic surface for nucleating a high-k gate dielectric layer. In a preferred embodiment, seed layer 202 is less than about 5 angstroms thick. A first ALCVD process that uses a metal alkoxide precursor (as described above) may be applied to form seed layer 202 directly on the hydrophobic surface of substrate 200, without a buffer layer being present between the seed layer and the hydrophobic surface. Alternatively, a metal alkyl precursor (e.g., trimethylaluminum) may be used to form seed layer 202. Depending upon the precursor used, it may be necessary to complete only 1 to 3 growth cycles to form a seed layer of the desired thickness.

After forming seed layer 202 on substrate 200, a second ALCVD process may be applied to form high-k gate dielectric layer 225 on seed layer 202, generating the FIG. 2a structure. A metal halide precursor (e.g., a metal chloride) and steam may be alternately fed at selected flow rates into a CVD reactor, which is operated at a selected pressure while the substrate is maintained at a selected temperature, to generate high-k gate dielectric layer 225.

When using an appropriate precursor (or precursors) in that second ALCVD process, it may be possible to form a high-k gate dielectric layer that comprises hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, or lead zinc niobate. In a preferred embodiment, high-k gate dielectric layer 225 is between about 5 and about 20 angstroms thick. After forming high-k gate dielectric layer 225 on seed layer 202, metal gate electrodes 215 and 220 may be formed on high-k gate dielectric layer 225, as FIG. 2b illustrates. Metal gate electrodes 215 and 220 may be formed on high-k gate dielectric layer 225 using materials and process steps like those described above.

The method of the present invention may enable a high quality high-k gate dielectric layer to be formed directly on a hydrophobic surface of a substrate (e.g., a silicon containing substrate)—without a buffer layer being present between the high-k gate dielectric layer and the hydrophobic surface. By enabling such a high-k gate dielectric layer to be formed on a bufferless surface, it may be possible to substantially reduce the electrical thickness of the gate dielectric stack, which may facilitate high volume manufacture of devices with gate lengths of less than about 30 nm.

Although the foregoing description has specified certain steps and materials that may be used in the method of the present invention, those skilled in the art will appreciate that many modifications and substitutions may be made. Accordingly, all such modifications, substitutions and additions fall within the spirit and scope of the invention as defined by the appended claims.

What is claimed is:

1. A method for making a semiconductor device comprising:
applying an atomic layer chemical vapor deposition process to form a high-k gate dielectric layer directly on a hydrophobic surface of a substrate, the atomic layer chemical vapor deposition process initiating growth of the high-k gate dielectric layer in less than about twenty growth cycles.

2. The method of claim 1 wherein at least one growth cycle comprises:
introducing steam into a chemical vapor deposition reactor followed by introducing a purging gas into the reactor; and
introducing a metal alkoxide precursor into the reactor followed by introducing the purging gas into the reactor.

3. The method of claim 2 wherein the metal alkoxide precursor has the molecular formula M(OR)_{y}, in which M is a metal that is selected from the group consisting of hafnium, lanthanum, zirconium, titanium, tantalum, yttrium, and aluminum, R is an alkyl group, and y is between 3 and 5.

4. The method of claim 1 wherein the high-k gate dielectric layer is between about 5 angstroms and about 40 angstroms thick.

5. The method of claim 1 wherein the high-k gate dielectric layer comprises a material that is selected from the group consisting of hafnium oxide, lanthanum oxide, zirconium oxide, titanium oxide, tantalum oxide, yttrium oxide, and aluminum oxide.

6. The method of claim 1 wherein between about 10 growth cycles and about 40 growth cycles are completed to generate the high-k gate dielectric layer.

7. The method of claim 1 further comprising forming a metal gate electrode on the high-k gate dielectric layer.

8. A method for making a semiconductor device comprising:
exposing a silicon containing substrate to hydrogen to generate a hydrophobic surface on the silicon containing substrate; and
applying an atomic layer chemical vapor deposition process to form a high-k gate dielectric layer directly on the hydrophobic surface, the atomic layer chemical vapor deposition process comprising:
introducing steam into a chemical vapor deposition reactor followed by introducing a purging gas into the reactor; and
introducing a metal alkoxide precursor into the reactor followed by introducing the purging gas into the reactor.

9. The method of claim 8 wherein the silicon containing substrate is exposed to hydrofluoric acid to generate the hydrophobic surface on the silicon containing substrate.

10. The method of claim 8 wherein the metal alkoxide precursor has the molecular formula M(OR)_{y}, in which M is a metal that is selected from the group consisting of hafnium, lanthanum, zirconium, titanium, tantalum, yttrium, and aluminum, R is an alkyl group, and y is between 3 and 5.

11. The method of claim 8 further comprising forming a metal gate electrode on the high-k gate dielectric layer.

12. The method of claim 8 wherein the high-k gate dielectric layer is between about 5 angstroms and about 20 angstroms thick.

13. A method for making a semiconductor device comprising:
exposing a silicon containing substrate to hydrofluoric acid to generate a hydrophobic surface on the silicon containing substrate;
forming a seed layer on the hydrophobic surface for nucleating a high-k gate dielectric layer;
forming a high-k gate dielectric layer on the seed layer; and
forming a metal gate electrode on the high-k gate dielectric layer.

14. The method of claim 13 wherein a metal alkyl precursor is introduced into a chemical vapor deposition reactor to form the seed layer directly on the hydrophobic surface, without a buffer layer being present between the seed layer and the hydrophobic surface.

15. The method of claim 14 wherein the metal alkyl precursor is trimethylaluminum.

16. The method of claim 13 wherein a metal alkoxide precursor is introduced into a chemical vapor deposition reactor to form the seed layer directly on the hydrophobic surface, without a buffer layer being present between the seed layer and the hydrophobic surface.

17. The method of claim 16 wherein the metal alkoxide precursor has the molecular formula M(OR)_{y}, in which M is a metal that is selected from the group consisting of hafnium, lanthanum, zirconium, titanium, tantalum, yttrium, and aluminum, R is an alkyl group, and y is between 3 and 5.

18. The method of claim 13 wherein a metal halide precursor is introduced into a chemical vapor deposition reactor to form the high-k gate dielectric layer on the seed layer.

19. The method of claim 13 wherein the high-k gate dielectric layer is selected from the group consisting of hafnium oxide, hafnium silicon oxide, lanthanum oxide, lanthanum aluminum oxide, zirconium oxide, zirconium silicon oxide, titanium oxide, tantalum oxide, barium strontium titanium oxide, barium titanium oxide, strontium titanium oxide, yttrium oxide, aluminum oxide, lead scandium tantalum oxide, and lead zinc niobate.

20. The method of claim 13 wherein the seed layer is less than about 5 angstroms thick, and the high-k gate dielectric layer is between about 5 angstroms and about 20 angstroms thick.
